(19) United States
(12) Patent Application Publication
(10) Pub. No.: US 2015/0195897 A1
(43) Pub. Date: Jul. 9, 2015

(54) Apparatus having management of electrical power capacity regions and management of thermal capacity regions

(71) Applicants: Joseph A. Swift, Dolgeville, NY (US); Chad Edward Miller, Florence, MT (US)

(72) Inventors: Joseph A. Swift, Dolgeville, NY (US); Chad Edward Miller, Florence, MT (US)

(21) Appl. No.: 13/999,054

(22) Filed: Jan. 8, 2014

(51) Int. Cl. H05K 1/02

(52) U.S. Cl. CPC H05K 1/0203; H05K 1/0213

(57) ABSTRACT

Provided herein is an apparatus having management of electrical power capacity regions and management of thermal capacity regions including a substrate member region having a length, a width, a thickness, and a surface area. The substrate member region may include a host binder material consisting of a polymer, a thermal plastic polymer, a thermo setting polymer, an intrinsically conductive polymer, an elastomer, a ceramic, a glass, a cement, a metal, a synthetic metal, combinations and mixtures of the above and the like, at least one conductive region for management of electrical power capacity and at least one conductive region for management of thermal capacity and at least one non-conductive regions. At least one of the regions for management of electrical power capacity and, optionally, at least one of the regions for management of thermal capacity as well as non-conductive regions may include an exposed surface for contact with another surface of a functional device.

### CROSS-REFERENCE TO RELATED APPLICATIONS

None

### STATEMENT REGARDING FEDERALLY SPONSORED RESEARCH OR DEVELOPMENT

None

### THE NAMES OF THE PARTIES TO A JOINT RESEARCH AGREEMENT

None

### BACKGROUND OF THE INVENTION

Means of transporting electricity are known. Likewise, means of insulating electrical conductors are also known. It is not unusual to notice that the means of insulating electrical circuitry may heat up. For example, when the current flow is more than an extension cord is rated to handle the insulating layer can feel hot to the touch. In extreme cases, the insulation may even melt or burn. The conduction of heat through the electrical insulating material in such circumstances is not unexpected. However, an extension cord is not necessarily designed so that the electrical insulating material serves as a management of the thermal capacity region.

Thermal conductivity of thermoplastic compounds may be directionally oriented dependent upon when high aspect ratio additives (fibers, flakes, etc.) are used and how they are compounded into their host resin because they tend to align with polymer flow during processing events such as extrusion. Certain orientations may result in non-isotropic thermal conductivity where values in-plane tend to be higher than through-plane values. Higher in-plane conductivities may be beneficial in dissipation of heat away from a single point source in a preferred direction. The RTP Co. (http://www.rtpcompany.com) provides a description of a variety of thermoplastic compounds. These thermoplastic compounds include: conductive compounds for reducing vehicle weight by replacing metal and for use in members such as enhanced LED luminaires Conductive thermoplastic compounds offer reliability and value for applications that require dissipation of electrostatic charges, protection from electrostatic discharge (ESD), or thermal management. Specialty compounds may be tailored to offer electrical properties spanning the surface resistivity spectrum from 10⁰ to 10¹² ohm/sq and formulated for injection molding or extrusion processing. Multiple technologies are available to impart conductive properties into thermoplastic resins. Each offers different approaches to providing the exact degree of conductivity required for a specific application, whether anti-static, static dissipative, ESD protection, conductive, or EMI/RFI shielding. In addition, conductive polymers, also referred to as intrinsically conductive polymers, may be alloyed with host resins and a variety of conductive particulates or fibers may be combined with a base member polymer to form a conductive composite.

Conductive thermoplastic compounds are divided into major classifications based on their electrical properties and decay rates for static charges. Insulative compounds (>10¹⁴ ohm/sq) Anti-Static Compounds (10⁹ to 10¹⁴ ohm/sq) that provide a very slow rate of decay of static charge, from hundredths of seconds to several seconds thereby preventing accumulations that may be a source of electrostatic discharge which may affect or initiate other nearby electrical events. Static Dissipative Compounds (10⁵ to 10⁹ ohm/sq) allow for the dissipation or decay of electrical charges at a much faster rate than anti-static materials, generally within milliseconds. Measured resistance is uniform and usually strong. Compounds available include carbon particulate filled polymers from a variety of commercial sources. Conductive compounds (<10⁵ ohm/sq) exhibiting electrostatic decay rates measured in nanoseconds are adequate for a broad range of applications. This level of conductivity is typically achieved by incorporating carbon fiber, high levels of carbon powder, or other conductive additives into a host resin, e.g., a thermal or thermal setting polymer. A wide variety of such compounds are available commercially form a variety of manufacturers. EMI/RFI shielding compounds having even higher electrical conductivity (10¹ to 10⁴ ohm/sq) are also available commercially from sources such as RTP, Co.

Qualified by means other than electrical conductivity, materials of this type are utilized for their ability to absorb or reflect electromagnetic energy and thus provide shielding from or for sources of interference. Products that provide shielding properties utilize stainless steel or metalized fibers and are offered in the various EMI products which are also commercially available.

Despite the many types of conductive compounds available, most, if not all exhibit a known non-ohmic behavior which is a decrease in measured resistivity as a function of the applied field. Conductive compounds that effectively bleed off high static charge levels which can reach tens or thousands of volts do not function well at low applied voltages and may even appear to be no better for passing low energy currents than an insulator. For many electric and particularly for electronic circuit's instabilities in a circuit resistance such as those stemming from non-ohmic behavior can cause serious failure modes in the operating circuit. Further, the measured resistance of electrically conductive composites and the measured thermal conductivity of thermally conductive composites may change as a function of the temperature that the composite resides. For large area conductive composites, large changes in measured conductivity can result from not only the steady state environmental temperature but also local temperature variations within the composite. Thus there is still a need for apparatus containing management of power capacity regions and management of thermal capacity regions. This need, and others, is provided for by the various embodiments of the invention as described herein.

### DESCRIPTION OF RELATED ART

U.S. Pat. No. 5,267,866 (Swift et. al, issued Dec. 7, 1993.) discloses a flexible electrical interconnect based on a hinge member having electric circuitry on several surfaces. U.S. Pat. No. 7,220,131, (Swift, et. al. issued May 22, 2007) discloses an electromechanical device with bundles of conducting fibers as interconnects between two planes. U.S. Pat. No. 7,052,763 (Swift et. al. issued May 30, 2006) discloses a multi-element configuration for management of power capacity and comprising various regions for management of thermal capacity as well as non-conductive regions. U.S. Pat. No. 7,266,322 B2 (Swift, et. al, issued Sep. 4, 2007) discloses a multifunctional element.

### BRIEF SUMMARY OF THE INVENTION

Disclosed herein in several embodiments is an apparatus having management of electrical power capacity regions and management of thermal capacity regions.

In certain embodiments, provided herein is an apparatus having management of electrical power capacity regions and management of thermal capacity regions including a substrate member region having a length, a width, a thickness, and a surface area. The substrate member region may include a host binder material consisting of a polymer, a thermal plastic polymer, a thermo setting polymer, an intrinsically conductive polymer, an elastomer, a ceramic, a glass, a cement, a metal, a synthetic metal, combinations and mixtures of the above and the like, at least one conductive region for management of electrical power capacity and at least one conductive region for management of thermal capacity and at least one non-conductive region. Each of the conductive regions for management of electrical power capacity and regions for management of thermal capacity and optionally the non-conductive regions have a length and an imaginary axis. The at least one conductive region for management of electrical power capacity and at least one conductive region for management of thermal capacity and optionally the non-conductive regions comprises at least one fiber and a host binder material. The fibers contained within the at least one electrical conducting region for management of electrical power capacity and the at least one heat conducting region for management of thermal capacity as well as non-conductive region fibers are configured in a relation to each other and in association with the host binder material. The region for management of electrical power capacity and at least one region for management of thermal capacity as well as the at least one non-conductive region are disposed in the substrate member and are selectively situated with respect to each other and may, in certain embodiments, form a matrix configuration including at least one selected dimension between the imaginary axis of the at least one region for management of electrical power capacity or at least one selected dimension between the imaginary axis of the at least one region for management of thermal capacity as well as at least one selected dimension between an imaginary axis of the at least one non-conductive region and including at least one selected dimension between the imaginary axis of the at least one non-conductive regions. One or more of the stated dimensions may have any value including zero. In this embodiment a polymer is selected for the host binder, i.e., the substrate member which is solidified about at least a portion of a periphery of the at least one region for management of electrical power capacity or at least a portion of a periphery of the at least one region for management of thermal capacity as well as non-conductive regions and is solidified about at least a portion of a periphery of the at least one non-conductive regions forming an integral structure. At least one of the regions for management of electrical power capacity and, optionally, at least one of the regions for management of thermal capacity as well as the optional non-conductive regions may include an exposed surface for contact with another surface of a functional device, for example a surface mounted accessory requiring transfer of electric or thermal energy.

In another embodiment of the invention herein, provided is an apparatus including a region as a substrate member comprising a length, a width, a thickness, and a polymer or intrinsically conductive polymer selected from the group consisting of polyethylene, polypropylene, polystyrene, polyvinylchloride, nylon, polyester, polyimide, polyphenelyene sulfide, poly ether ether ketone, polyimideamide, polyetherimide, polyurethane, vinyl ester, epoxy, polyvinyls, poly-cellulose derivatives, fluoroelastomers, polysiloxanes, polysilanes, polycarbazoles, polyphenothiazines, polyetherketones, polyetherimides, polyethersulphones, polyurethanes, polyether urethanes, polyester urethanes, polytetrafluoroethylenes, polycarbonates, polyacrylonitriles, poly(ester-imides), polyfluoroalkoxys, poly(amide-imides), polymers synthesized from a methyl methacrylate monomer and a bisphenol monomer, polyacetylene, polyphenylene vinylene, polypyrrole, polythiophene, polyaniline, polyphenylene sulfide, and copolymers and mixtures thereof.

In another embodiment of the invention herein, provided is an apparatus including a substrate member comprising a length, a width, a thickness, the substrate member comprising a material selected from the group consisting of a polymer, a thermal plastic polymer, a thermo setting polymer, an intrinsically conductive polymer, an elastomer, a ceramic, a glass, a cement, a metal, a synthetic metal, a cermet, combinations and mixtures of the above and the like; a conducting region selected from the group consisting of a pultruded region, a mold formed region, an extruded formed region, a lay-up formed region for management of electrical power capacity or for management of thermal capacity, and at least one non-conductive regions. The at least one region for management of electrical power capacity or at least one region for management of thermal capacity may include pultruded composite regions including at least one conductive carbon fiber and a polymer material such as polyester, polyimide, nylon, epoxy and the like. The at least one conductive carbon fiber is configured in a relation to other carbon fibers and in association with the polymer material. Each region for management of electric power capacity and region for management of thermal capacity has a first end and a second end. The at least one non-conductive region may include at least one non-conductive fiber. Each non-conductive region has a first end and a second end. The at least one region for management of electrical power capacity and regions for management of thermal capacity as well as non-conductive regions are disposed in the apparatus as a substrate member and are selectively situated with respect to each other and may, in certain embodiments, form a matrix configuration including at least one selected dimension between the imaginary axis of at least one region for management of power capacity or regions for management of thermal capacity as well as non-conductive pultruded composite regions and including at least one selected dimension between the imaginary axis of the non-conductive regions. The matrix having an enhanced mechanical strength that results from a synergistic combination of the fibers, host polymer, and process. The polymer of the substrate member region is solidified about at least a portion of a periphery of the at least one region for management of electrical power capacity or about at least a portion of a periphery of the at least one region for management of thermal capacity as well as non-conductive regions and is solidified about at least a portion of a periphery of the at least one non-conductive region forming an integral structure. At least one region for management of electrical power capacity or one region for management of thermal capacity is accessible at a portion of the substrate member for contact with an electric power source or heat source or a power- or heat-requiring member.

In a further embodiment of the invention herein, provided is an apparatus having at least one conductive fiber blended with a host polymer by an extrusion process to create regions for management of electrical power capacity and regions for management of thermal capacity and a substrate member region including a length, a width, a thickness, the substrate member region having a thermal plastic polymer, and at least one region for management of electrical power capacity and at least one region for management of thermal capacity as well as non-conductive regions. For the at least one region for management of electrical power capacity and/or at least one region for management of thermal capacity as well as non-conductive regions, each region having a first end, a second end, and a length. The apparatus includes at least one region for management of electrical power capacity and at least one region for management of thermal capacity as well as non-conductive regions, each of the regions including a plurality of fibers extending in the regions. The regions each being mechanically integrated into a substrate member. The at least one region for management of electrical power and/or management of thermal capacity may be disposed in a substrate member and are selectively situated with respect to each other and may form a geometric configuration including at least one selected dimension between the imaginary axis of at least one region for management of electrical power and/or management of thermal capacity; wherein the polymer of the substrate member region is solidified about at least a portion of a periphery of the at least one region for management of electrical power and/or management of thermal capacity forming an integral structure.

Embodiments are provided of various apparatus having at least one region for management of electrical power capacity and at least one region for management of thermal capacity. In embodiments, the apparatus having regions for management of electrical power capacity and regions for management of thermal capacity as well as non-conductive regions may be used in the electronics industry, for such applications as, e.g., integrated circuits, test systems, electrical systems, power and signal circuitry and in association with systems such as, for example, electrical test equipment, communications equipment, computers and peripherals, analog or digital systems including audio and video transmission and reproduction systems.

### BRIEF DESCRIPTION OF THE SEVERAL VIEWS OF THE DRAWING

Accordingly, the figures and description are to be regarded as illustrative in nature, and not as restrictive or limiting.

FIGS. 1a, 1b, and 1c depict cross-sectional views of embodiments of an apparatus having at least one region for management of power capacity and at least one regions for management of thermal capacity regions having an array of regions for management of power capacity and regions for management of thermal capacity as well as non-conductive regions.

FIGS. 2a and 2b depict cross-sectional views of embodiments of adjacent regions for management of power capacity and regions for management of thermal capacity as well as non-conductive regions arrays configured to contain m rows of regions for management of power and n columns of regions for management of thermal capacity.

FIG. 3 depicts a cross sectional view of an embodiment of a rectangular array of modular adjacent substrates having regions for management of power capacity and regions for management of thermal capacity as well as non-conductive regions;

FIGS. 4a and 4b depict a cross-sectional view of embodiments of an integrated rectangular array;

FIG. 5 depicts a side view of embodiment profiles of the management of power capacity regions and management of thermal capacity regions extending in or through a substrate;

FIGS. 6, 6a, and 6b depict a top, front and side views of an embodiment of a multilayer component having management of power capacity regions and management of thermal capacity regions adapted for a surface mounted electrical component device;

FIG. 7 illustrates an exemplary embodiment of an interconnect capable of providing electrical power or signal to and/or sensing the electrical potential of a member;

FIG. 8 illustrates a further exemplary embodiment of an interconnect capable of providing electrical power or signal to and/or sensing the electrical potential of a member.

### DETAILED DESCRIPTION

The expression “region(s) for management of electrical power capacity” as used herein refers to portion(s) of the claimed apparatus which are useful for movement and storage of electrical potential. The electrical potential may be any voltage and may include alternating current of any frequency including radio and microwave frequencies, direct current, or mixed currents, and, may take on any value including very low potentials typical of low level signal currents.

The expression “regions for management of thermal capacity” as used herein refers to portions of the claimed apparatus which are useful for movement and storage of thermal energy.

The expression “conductive fibers” as utilized herein is intended to be inclusive of carbon fibers made by heat conversion of any suitable precursor such as pitch, including mesophase, polyacrylonitrile (PAN), rayon, PBI and other such materials as well as metalized carbon fibers, synthetic metal fibers, metal fibers, metalized glass or ceramic fibers, metalized natural or mineral fibers, such as metalized wool, metalized basalt, metalized cotton, and the like. The fibers may be of any size, shape, length, and cross-sectional design including those having a variation of composition within the perimeter of the individual fiber's cross section.

The expression “at least one conductive fiber” as utilized herein refers to single monofilaments or assemblages of monofilaments in continuous or non-continuous form including tows, veils, felts, cloths, braids, structured or non-structured arrays of fibers, including yarns, ropes, sheets and the like. The filaments may be of any size, shape, length, and cross-sectional design including those having a variation of composition within the perimeter of the individual filament's cross section. While metals are often chosen for their high thermal conductivity, many applications do not require this high level of thermal transfer. In fact, air movement (or convection) often determines how effectively a system can transfer and dissipate heat. On the other hand, heat movement by conduction processes in conductive members is typically most effective, particularly within solid members. Typically, thermally conductive compounds may be a reliable and effective means for heat transport while at the same time providing significant weight reduction over comparable performing metals such as those used in heat sinks. Weight reduction often is associated with overall energy consumption in many applications such as transportation, and is especially significant in contemporary energy conscious uses.

Selecting the proper composition in addition to providing for electrical and thermal conductivity may also provide a high degree of chemical resistance, and elimination of corrosion that may lead to failure of many components.

As mentioned above, a variety of commercial sources exist which manufacture and supply products having thermally conductive additives in a wide variety of plastic resins to produce conductive compounds optimized for thermal management in a wide range of operating temperatures and environments.

The invention herein, in certain embodiments, relates to apparatus having regions for management of power capacity and regions for management of thermal capacity as well as non-conductive regions suitable for use in the electronics industry for electronics packaging and in electrical systems. Other industries include transportation, aerospace, communications, construction, energy, business machines, and armament in either the commercial or military sectors.

It is generally known within the molding, extrusion and pultrusion industries that fibers may be combined with resins to form a configuration of fibers that serve as a reinforcing filler material bound by host resin. Applying pultrusion methods, for example to produce, a carbon fiber rich composite enables high strength to be obtained and allows many forms of the carbon fiber to be manufactured into various design shapes and configurations, such as, solid rods, tubes, plates, I-beams, and thin flat sheets. Moreover, the carbon fibers, carbon nanotubes, metalized carbon fibers, or combinations of carbon and other conducting fibers or fillers used in polymer composites are considered, generally, to be of high electrical conductivity as well as high strength and capable of providing statistically regular and evenly distributed electrical contact sites for charge or current conduction across an interface. Pultrusion methods involve, e.g., (1) pulling continuous lengths of regions, such as fibers or tows, through a host binder material, such as a liquid polymer, heat melted polymer, polymer in solution, a liquid metal, such as a eutectic metal, or combinations thereof, to form an intermediate composition, (2) pulling the intermediate through a die to shape the composition, and (3) pulling the composition through a heated region to enable the composition to cure (e.g. cross-link), freeze, or dry. Moreover, the conductive fibers, when used in carbon fiber polymer composites are considered, generally, as contact rich and capable of providing statistically regular and evenly distributed electrical contact sites when they protrude or project in or onto a contact surface. In addition, because carbon is generally non-reactive and less susceptible to corrosion when compared to other materials, such as, ferrous metals or cupreous metals, carbon fiber may be used in harsh environments or corrosive environments, including saltwater, nuclear power environments, space, medical, and biological applications.

By example, thin, non-woven sheets of random oriented carbon fiber which are referred to as veils are used as protective surface layers on pultruded I-beams, rails, boards, and structural regions to improve surface abrasion characteristics and alter the surface topography of the member. The veil layer in these structures also imparts an irregular surface texture to the surface, which is absent in general, in continuous fiber reinforced pultrusions, which may help with adhesive bonding and reduce surface wear. The presence of a carbon fiber veil at the surface of a member provides for surface- or near to the surface-conductivity. High modulus materials within rigid composite shapes may be formed by inserting carbon fiber materials where needed to provide high strength as well as conductivity within the profile geometry. A fiber structure that is tubular in cross-section consisting of carbon fibers surrounded by a combination of fiberglass and resin is generally known.

Reference is made to pultrusion, contacts, and regions for management of power capacity and regions for heat management of thermal capacity as well as non-conductive regions in U.S. Pat. Nos. 4,330,349; 4,841,099; 4,970,553; 5,139,862; 5,167,512; 5,220,481; 5,250,756; 5,267,866; 5,270,106; 5,281,771; 5,354,607; 5,366,773; 5,410,386; 5,414,216; 5,420,465; 5,492,743; 5,599,615; 5,689,791; 5,744,090; 5,756,998; 5,794,100; 5,812,908; 5,843,567; 6,214,921; 6,217,341; 6,265,046; and 6,289,187. All documents cited herein, including the foregoing, are incorporated herein by reference in their entireties for all purposes.

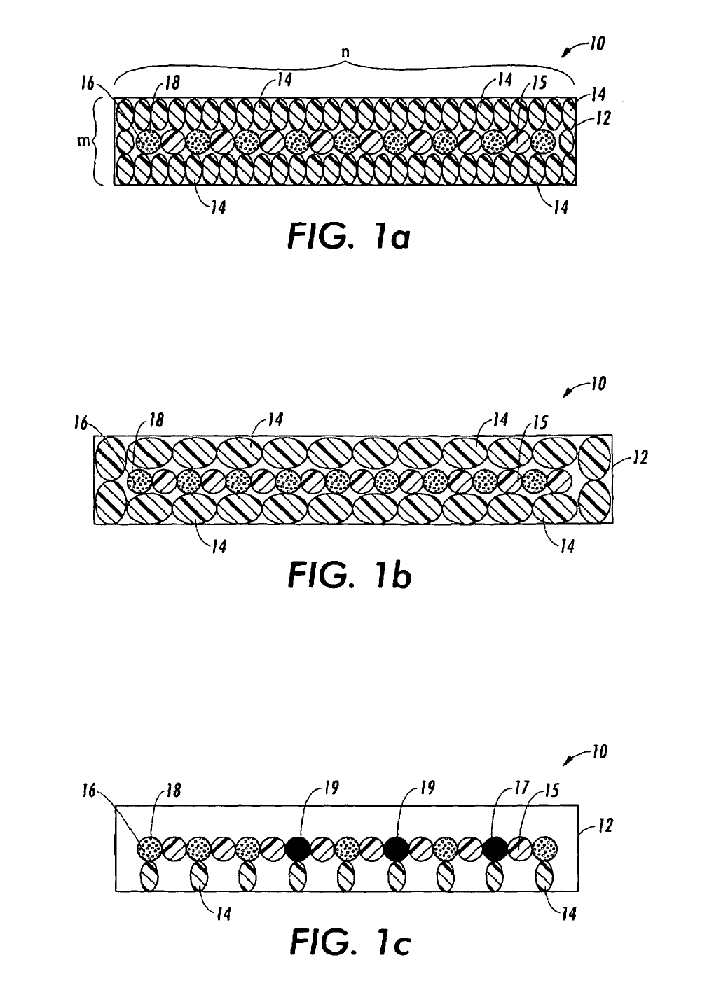

Reference is made to embodiments of FIGS. 1-8 illustrating modular and integrated features of various regions for management of power capacity and regions for management of thermal capacity as well as non-conductive regions.

FIG. 1a depicts a cross-sectional view of an embodiment of an apparatus 10 including regions for management of power capacity 18 and regions for management of thermal capacity 15 as well as insulating regions, generally non-conductive spacer fibers 14 including a single row of regions for management of power capacity 18 including conductive fibers 16 in a substrate member region 12. Regions for management of thermal capacity 15 are also shown in the row between regions for management of power capacity 18. Also, generally non-conductive spacer fibers 14 formed in a substrate member region 12 may be disposed about the periphery of the row of regions for management of power capacity 18 and regions for management of thermal capacity 15. The substrate member region 12 comprises a suitable binder resin and suitable fibers forming a selected array design. Insulating regions may e.g., generally non-conductive spacer fibers 14 include non-conductive monofilaments, arrays of fibers, yarns, tows, sheets having non-conductive fibers, fillers, and the like. The array is referred to as an [m×n] array where m refers to the number of rows of regions for management of power capacity 18, regions for management of thermal capacity 15 or non-conductive regions 14 and n defines the number of columns of regions for management of power capacity, regions for management of thermal capacity or non-conductive regions. The regions for management of power capacity 18 and regions for management of thermal capacity 15 as well as non-conductive regions 14 may include a selected configuration of regions for management of power capacity 18 in an m×n array, for example, m=1 row and n=9 columns in FIG. 1a.

Regions for management of power capacity 18 in an apparatus 10 having regions for management of power capacity 18 and regions for management of thermal capacity 15 as well as non-conductive regions 14 are suitable for contact with an electric circuit member such as a power or signal source or a signal or power requiring member. By example, an integrated circuit (IC) during its burn-in testing typically conducted during post-manufacture, final acceptance testing requires a temporary, but highly reliable connection to an IC socket, which in turn is interconnected to an electrical testing apparatus. The temporary interface requires not only precise control of the electrical interconnections but also the thermal management of the temporary assembly. Burn-in final quality testing may result in false rejections of otherwise acceptable ICs in the event where the IC to socket reliability is unreliable. Likewise, permanent assembly of ICs into permanent IC sockets require similar ultra-high reliability and precise management of both electrical and thermal energies, which are provided for in a lightweight, high strength assembly. In this example, the regions for management of power capacity 18 may be configured to allow removal and replacement of either a bare or packaged chip into the next level electronic package.

FIG. 1 b illustrates a cross-sectional view of an embodiment of an apparatus 10 including regions for management of power capacity 18 and regions for management of thermal capacity 15 as well as non-conductive regions 14 including generally non-conductive fibers 14 that are used to space the regions for management of power capacity 18 in the array and provide mechanical strength or isolation or insulation amongst the conductive regions for management of power capacity 18.

FIG. 1c illustrates a cross-sectional view of an embodiment of an apparatus 10 including regions for management of power capacity 18 and regions for management of thermal capacity 15 as well as non-conductive regions 14 forming a substrate member 12 including conductive regions for management of power capacity 18 having carbon fibers 16 and other “secondary” conductive contacts 19 which may include metal fibers or wires and other “tertiary” conductive contacts 17 which may include metallized glass or optically transmissive glass or plastic, or ceramic or other thermally conductive fiber such as pitch carbon fiber. Generally non-conductive fibers 14 and/or regions for management of thermal capacity may be provided to space the regions for management of power capacity 18 in the array.

In certain embodiments, the regions for thermal management may comprise thermally conductive fibers or fillers for applications where micro- or macro-movement of heat within or out of the member may be required.

In certain embodiments, the regions for management of power capacity 18 and regions for management of thermal capacity 15 as well as non-conductive regions 14 may be made by a pultrusion process where about 50% or greater of the cross-sectional area comprises the fiber filler phase of the composite. Compression molding, resin transfer molding, filament winding, injection molding, sheet molding and laminating processes may also be used to form the regions for management of power capacity 18 and regions for management of thermal capacity 15 as well as non-conductive regions 14.

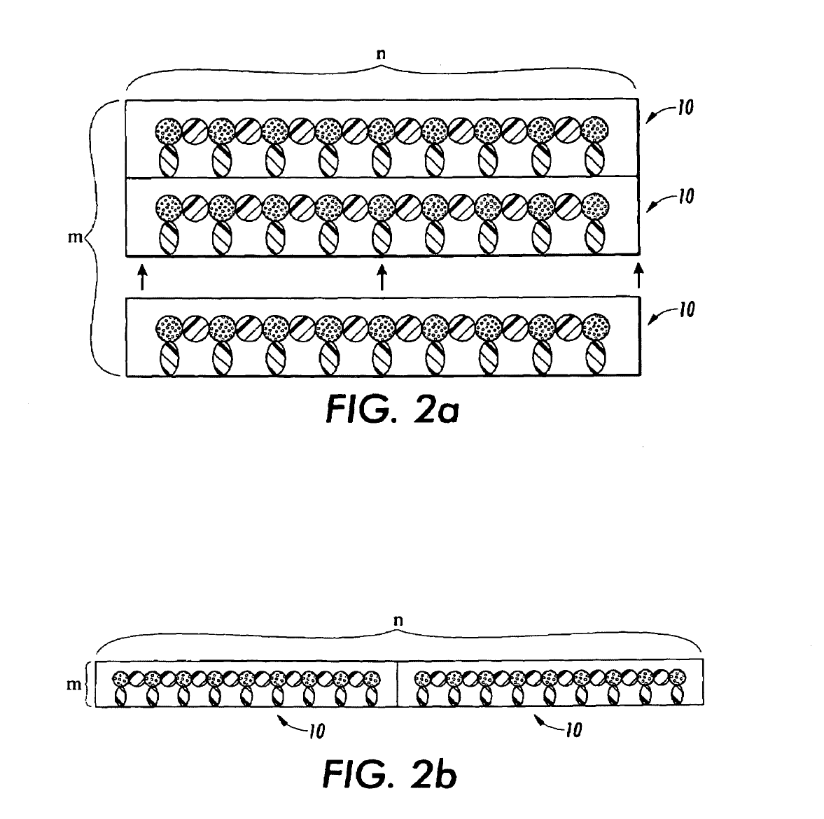

FIGS. 2a and 2b illustrate cross-sectional views of embodiments of apparatus 10 assembled to provide adjacent regions for management of power capacity 18 and regions for management of thermal capacity 15 as well as non-conductive regions 14 in accordance with FIGS. 1a, 1b, & 1c. The regions for management of power capacity 18 and regions for management of thermal capacity 15 as well as non-conductive regions 14 may be pre-configured into a (1×n) array and then be aligned into selected configurations such as a side-by-side regions for management of power capacity 18 and regions for management of thermal capacity 15 as well as non-conductive regions 14 system (FIG. 2a) or a length-to-length regions for management of power capacity 18 and regions for management of thermal capacity 15 as well as non-conductive regions 14 system (FIG. 2b), or combinations thereof resulting in an regions for management of power capacity 18 and regions for management of thermal capacity 15 as well as non-conductive regions 14 system having selected dimensions and contact features.

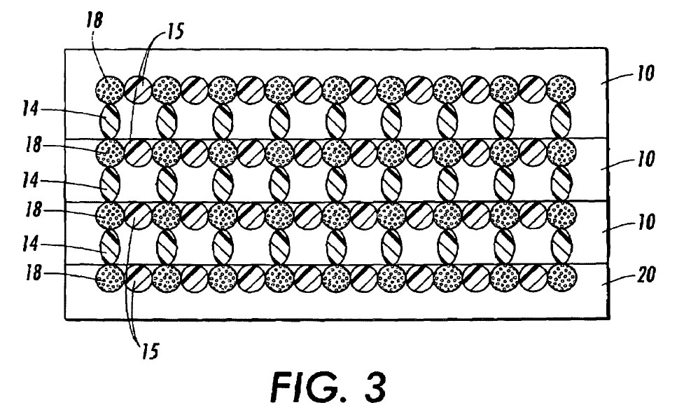

FIG. 3 illustrates a cross-sectional view of an embodiment of an array of regions for management of power capacity 18 and regions for management of thermal capacity 15 as well as non-conductive regions 14, including apparatus modules or articles of manufacture 10, 10, 10, 20 situated in a relation to another. Regions for management of power capacity 18 and regions for management of thermal capacity 15 as well as non-conductive regions 14 is an embodiment of an article of manufacture including regions for management of power capacity 18 and regions for management of thermal capacity as well 15 as non-conductive regions 14 including one row of alternating regions for management of power capacity 18 and regions for management of thermal capacity 15. Regions for management of power capacity 18 and regions for management of thermal capacity 15 are formed without an adjacent row of generally non-conductive spacer fibers 14. It is envisioned that an array of regions for management of power capacity 18 and regions for management of thermal capacity 15 as well as non-conductive regions 14 may include one or more adjacent regions for management of power capacity 18 and regions for management of thermal capacity 15 as well as non-conductive regions 14 to form substrate members 12 including apparatus modules or articles of manufacture 10, 20 as well as combinations of other regions for management of power capacity and regions for management of thermal capacity as well as non-conductive regions or modules having selected features. Other regions for management of power capacity 18 and regions for management of thermal capacity 15 as well as non-conductive regions 14 designs including combinations of contacts 17, 19 and regions for management of power capacity 18 along with regions for management of thermal capacity 15, and generally non-conductive spacer fibers 14 of varying dimension, position, shape, function, and features, including superior mechanical strength features are envisioned.

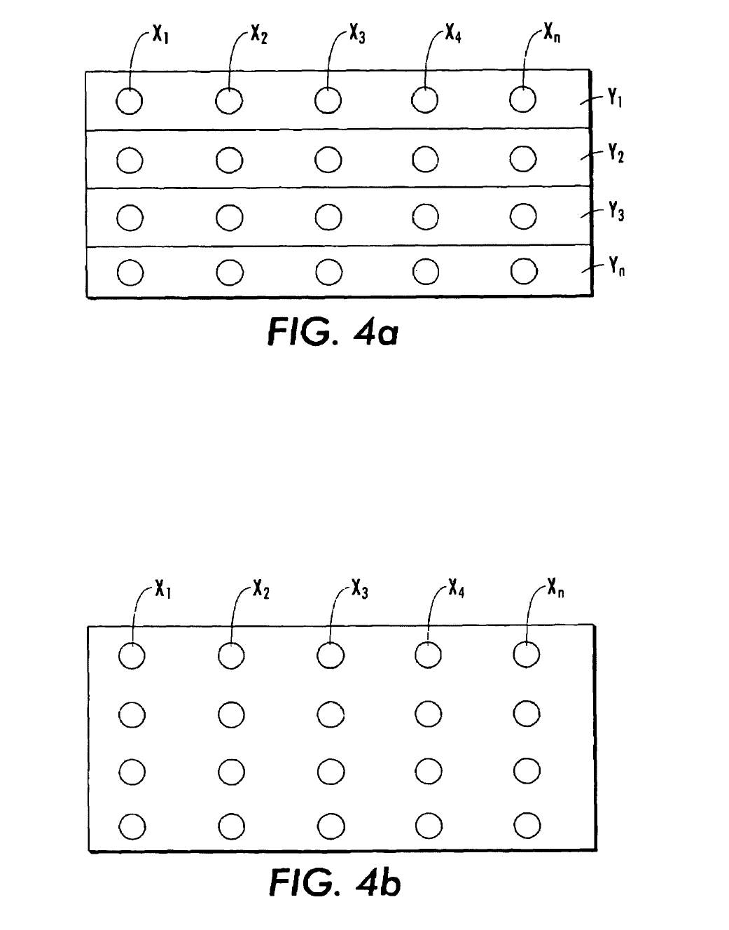

FIGS. 4a and 4b illustrate the selectability of design, position, alignment, density, and number of contacts in the regions for management of power capacity 18 and regions for management of thermal capacity 15 as well as non-conductive regions 14 as well as the modularity of the array and regions for management of power capacity 18 and regions for management of thermal capacity 15 as well as non-conductive regions 14. In embodiments, an array comprising a selected number of regions as a substrate regions Y in association with another is provided as shown in FIG. 4a. The substrate member region(s) Y comprise a selected number of interspersed regions X. The substrate member region(s) Y or regions for management of power capacity 18 and regions for management of thermal capacity 15 as well as non-conductive regions 14 may be joined by thermal, chemical or mechanical systems or combinations thereof. The substrate member region(s) Y may include distinct insulative regions or it may itself be made of an electrically insulative or partially electrically insulative material that is optionally thermally conducting or insulative. Thus, t substrate member region Y may be thermally conductive and electrically insulative. In embodiments, an array of regions X may be formed as a fully integrated array of FIG. 4b including non-conductive spacer fiber 14 and regions for management of thermal capacity 15 and conductive regions 17, 19 along with regions for management of power capacity 18 in selected size and matrix form.

In embodiments, the use of selectively configured fiber or filament containing composites in regions for management of power capacity 18 and regions for management of thermal capacity 15 as well as non-conductive regions 14 as contacts or interconnects between on member such as an IC chip and a circuit may increase the reliability of the individual contact sites in various applications. The conductive elements may be configured such that the conductive contacts 17, 19 of the regions for management of power capacity 18 and regions for management of thermal capacity 15 as well as non-conductive regions 14 establish interconnections with pads, pins, contacts, feet, or lands of a mated device or member and an electrical or thermal circuit as selected.

In embodiments, the regions for management of power capacity 18 and regions for management of thermal capacity 15 as well as non-conductive regions 14 may be configured as an integrated, separable electric interconnect device and provide a package system for, for example an IC chip. The regions for management of power capacity 18 and regions for management of thermal capacity 15 as well as non-conductive regions 14 in a substrate member 12 provides modularity and is generally suitable for mass manufacturing. Various shapes and sizes of the substrate member region 12 and positioning and density of the conductive regions 17, 19, regions for management of power capacity 18 and regions for management of thermal capacity 15 and non-conductive regions 14 therein are envisioned. Substrate member region 12 comprising square, rectangular, triangular, round, non-circular, and irregular geometric shapes and dimensions are envisioned. The dimensions, density, spacing, and matrix configuration of the conductive regions 17, 19, regions for management of power capacity 18 and regions for management of thermal capacity 15 and non-conductive regions 14 in the substrate member region 12 are selected and sized to suitably mate with contacts of an IC chip or circuitry.

In embodiments, regions for management of power capacity 18 and regions for management of thermal capacity 15 may be formed into their matrix configuration in a number of ways, for example: (1) the regions for management of power capacity 18 or regions for management of thermal capacity 15 may be first pultruded to form a conductive pultruded composite member and then this pre-pultrusion is added to the non-conductive regions to form a final pultruded matrix; (2) co-pultrude both the regions for management of power capacity 18 and regions for management of thermal capacity 15 and non-conductive fibers 14 that are properly aligned and spaced into a final composite pultruded configuration; (3) pre-pultrude the non-conductive regions 14 into a pre-pultrusion and then combine this with the regions for management of power capacity 18 and regions for management of thermal capacity 15 to create a final matrix; or (4) pre-pultrude individually each of the regions for management of power capacity 18 and regions for management of thermal capacity 15 and non-conductive regions 14 and then co-pultrude these into a final matrix. In addition, other compositing techniques such as resin transfer molding, insert molding, rotary molding, and or layer-composite laminate molding may be used instead of pultrusion.

In embodiments, a pultrusion process may be used for making regions for management of power capacity 18 and regions for management of thermal capacity 15 as well as non-conductive regions 14 including a selected number of fiber integrated composite regions for management of power capacity 18, secondary contacts 19 and tertiary contacts 17, and insulating regions 14 within a substrate member region 12 made of a suitable host polymer. Alignment and dynamic feeding of electro- and thermo-conductive fibers into a pultrusion die results in an array of conductive sites 17, 19, inter-spaced by insulating fibers 14 or a substrate member region 12. The materials comprising regions for management of power capacity 18 and regions for management of thermal capacity 15, insulating fibers 14, and host resin are selected to provide high density contact packing, isolation resistance between contacts for reliable mating with the IC chip, and secondary manufacturing operations such as laser cutting suitability.

The fibers are fed and aligned at precise locations during the pultrusion process using guiding devices including guide plates such as thin rigid metal, wood, glass, ceramic, rubber, or plastic plates, or combinations thereof having hole patterns which correlate to the final desired array pattern and are then transformed into a rigid solid in the form of a substrate member 12 including regions for management of power capacity 18 and regions for management of thermal capacity 15 as well as non-conductive regions 14.

Alternatively, a modified pultrusion process that pre-assembles the conductive elements 17, 19 and/or regions for management of power capacity 18, regions for management of thermal capacity 15 and the insulating non-conductive regions 14 into pultruded “pre-forms” and subsequently co-pultrudes the pre-forms into the desired array as envisioned. In embodiments, it is envisioned that a suitable thermosetting or thermoplastic resin or other suitable host material be used for the pre-forms which is compatible with the host resin used for the final stage pultrusion. In cases where a similar thermosetting resin is employed, it may be undercured or partially cross linked during the pre-form formation process and fully cured during the final stage pultrusion process. This procedure helps to assure good adhesion between the pre-forms and other elements of the final assembly.

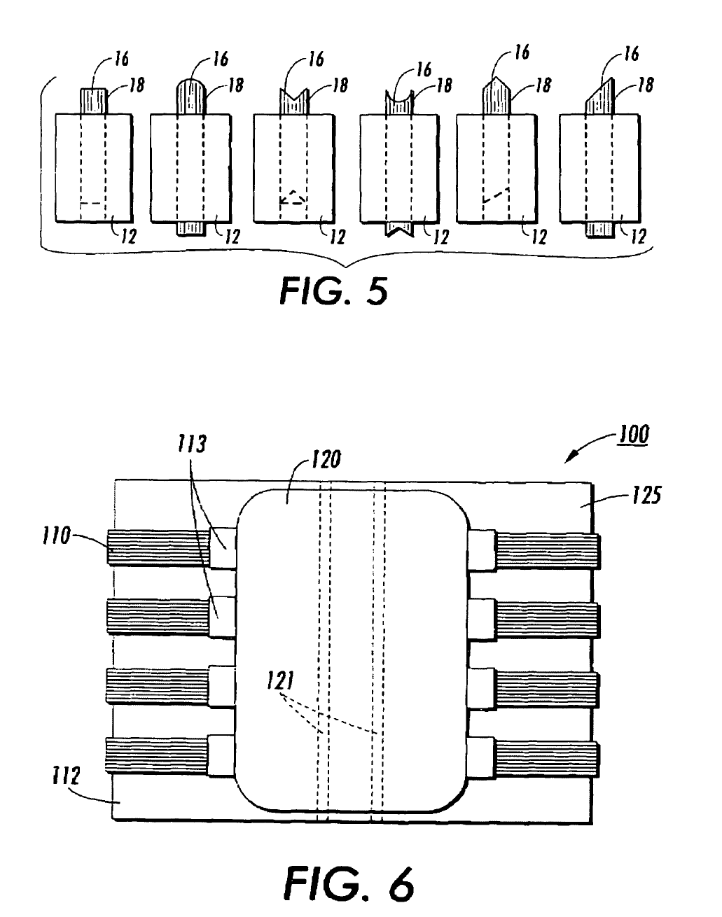

Reference is made to FIG. 5 illustrating embodiments of conductive contacts such as regions for management of power capacity contact 18 including profiles extending from the substrate member region 12, and profiles internal to the substrate member region 12. Combinations of the profiles internal and external to the substrate member region 12 are envisioned. A “heating-cutting” laser such as a CO2 or CO or YAG laser, or an excimer ablation-type laser may be used for the cutting process to shape a portion of the conductive regions for management of power capacity 18, regions for management of thermal capacity 15 and non-conductive region 14, or the substrate member region 12 after they have solidified into the composite form in order for the contact pads on the IC chip or other device or circuit elements to mate effectively therewith. Mechanical, abrasive, or water jet cutting methods may

+optionally be employed to cut and configure the configurations illustrated in FIG. 5. The regions for management of power capacity 18 and regions for management of thermal capacity 15 may be cut or sculpted into a variety of shapes including flat, angular, convex, concave, stepped, irregular, or combination surfaces at the ends or exposed portions of selected contacts. Fibrillated fibers that are fully or partially segregated from their host binder are flexible and may be formed on the contact at selected regions. For laser cutting, substrate member region 12 and insulating member material 14, 15 are selected such that their thermal decomposition temperatures are lower than that of the conductive regions 17, 18, 19. The energy of the laser is generally most effectively absorbed by material directly centered in the laser path and the material positioned in the center of the laser beam is cut. Conduction of some heat away from the cut region occurs with most materials selected for the binder resin and insulative elements 14, 15. Thermally stable carbon or metal-carbon fibers generally tolerate laser temperatures while the less thermally stable polymers vaporize leaving behind bumps of the conductive fibers.

Alternately, other suitable surface cutting methods may be used depending upon the desired cross-sectionalography of the final contact surfaces. For example, water jet cutting processes may be used in those cases where a relatively flat and smooth surface is desired.

Conductive fibers including carbonized polyacrylonitrile (PAN) fibers (metallized and metal plated PAN fibers) may be used as electro-conductive fibers in the conductive regions 18. Generally, the conductive contact 18 may comprise bundles or “tows” of, for example, 100 or 1000 or more individual carbon or metal carbon fibers. The insulating regions 14, 15 may comprise a sufficient number of fibers in yarns situated between the conductive regions 18. Polyamide (nylon), polyester (PET and PBT), rayon, acrylic, non-carbonized polyacrylonitrile, fiber glass, PEEK and copolymers, blends and mixtures thereof are examples of suitable insulative non-conductive fibers. The fibers may have sizes and shapes suitably selected for the design of the final assembly. The insulating fibers may have cross sections that are round, oval, multi-lobal, flat, solid or hollow as required by the final application. The substrate member region 12 may include a suitable thermal setting or thermal plastic resin which may be processed in the pultrusion process. The substrate member region may also be made of the same material as the insulating regions 14. Materials used in the system may also include polymeric fibers, glass, quartz, mineral, preoxidized PAN, partially carbonized PAN, optical fibers, metal fibers, metal alloy fibers and combinations thereof.

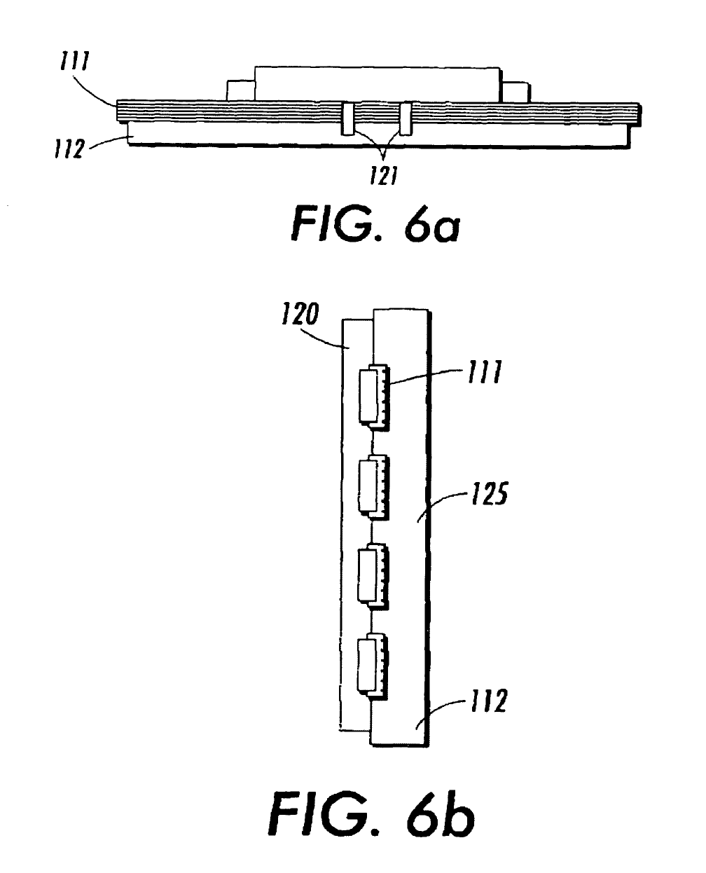

Reference is made to FIG. 6 illustrating an embodiment of a multilayer component assembly 100 including a surface mount electronic component device 120, such as an integrated circuit, associated with a base region as a substrate 125 using surface mount technology (SMT). The base region as a substrate 125 may include conductive materials including carbon fiber or other conductive filler within selected regions which serves as a location-specific interconnect medium. The assembly 100 may include conductive regions 110 including fibers and insulating regions 112 including fibers. Embedded conductive fibers are co-pultruded with non-conductive host material forming an N×M configuration, for example, n=4, m=1. End surfaces of the base region as a substrate 125 may be processed with a laser to expose and allow fiber areas 111 to extend from the body of the region as a substrate to facilitate connection to external circuitry. Electrical power and signal pins (not shown) may be used as surface mount interconnects for connecting the device 120 to the base region as a substrate 125. This configuration allows optional replacement of an assembly. One or more channels 121 or breaks in the conductive regions may be formed in the base region as a substrate to isolate signals as desired in the circuitry. FIG. 6a illustrates a front view of the multilayer component of FIG. 6. FIG. 6b illustrates an end view of the multilayer component of FIG. 6 including conductive terminations such as fiber-rich, fibrillated ends 111.

In embodiments, regions for management of power capacity and regions for management of thermal capacity as well as non-conductive regions system 100 provides miniaturization and integration of embedded electrical, thermal, and mechanical features. Electric and electronic components may be mounted to the substrates for point of mechanical, electrical, and thermal load-interfacing and terminations. A selected mating structure in the assembly 100 may be used to make the electrical interconnections to conventional wiring or PWB-type circuit boards, for example. A variety of regions for management of power capacity and regions for management of thermal capacity as well as non-conductive regions configurations are envisioned. The cross-section of the assembly 100 may be most any shape. More than one system may be mounted together including planar (for example, two-dimensional “2-D”) and non-planar (for example three-dimensional “3-D” configurations using conventional FR4 type 2-D and 3-D circuit boards as a mounting surface, for example.

In regions for management of power capacity and regions for management of thermal capacity as well as non-conductive regions embodiments, conductive regions 110 may be included in single or multi-layer configurations in the assembly 100. Selected surface and substrate preparation processes provide a reliable means for integration of electronic components such as surface mount devices and multi-layer regions for management of power capacity and regions for management of thermal capacity as well as non-conductive regions system. Embedded layer(s) with resistive properties may be used to eliminate the necessity for discrete resistive components on the surface of the region as a substrate. Applications of thermoplastic carbon fiber composites along with thermosetting materials are envisioned.

In regions for management of power capacity and regions for management of thermal capacity as well as non-conductive regions embodiments, portions of the conductive composite pultruded regions 110 may be mechanically or spatially separated from the surrounding non-conductive regions 112 and thereby may serve as a mechanical spring member at the point of contact with the device 120. This provides for an effective, reliable and independent-acting electro-mechanical and thermo-mechanical interconnect at every position on the device. A selected matrix configuration may include a conductive fiber region separated spatially and electrically from another conductive fiber region. The conductive member may be accessible along at least a portion of its length to provide a conductive surface area for contact with the circuit.

Generally soft, springy fiber rich contacts may be used for applications with moving objects and for point of load electronics for control or signal acquisition with the integration of the assembly components on the same substrate member region. In embodiments, the regions for management of power capacity and regions for management of thermal capacity as well as non-conductive regions systems provide a generally high level of integration with a robust, high temperature material, with a minimum of interconnection components and may be applied to various electronic assembly applications including circuitry such as micro-electronic devices, microprocessors, digital signal processing, embedded sensors, wireless communications, telecommunications, medical devices and medical probes.

In regions for management of power capacity and regions for management of thermal capacity as well as non-conductive regions embodiments, conductive composites may be used either as the primary or secondary region as a substrate. Electronic components may be fabricated on a PWB type material and then be affixed to the surface of a secondary composite region as a substrate that may optionally be part of the electrical circuit. A CO2, YAG, or excimer laser may be used for the formation of contact wells or pockets in the body of a composite material. The internal walls of the pocket may include fibrillated regions that may be either used for interference fit electrical contacts or for through-hole connections.

To make the interconnection between device 120 and selected sockets permanent, the electronic device 120 may be mounted to the regions for management of power capacity and regions for management of thermal capacity as well as non-conductive regions utilizing conductive adhesives, for example conductive epoxies or solder, or in combination with auxiliary region as a substrates augmented by PWB systems. The materials may be selectively constructed and formed to provide alternating conductive and non-conductive areas or circuited areas. The integration of the soft contacts at an assembly level provides generally cost effective and reliable electronic systems. Optionally the fibers that extend from the binder material may be long in comparison to the overall assembly 100 which may be combined using a secondary process, such as insert molding with another host material such as an elastomer thereby enabling the extension(s) to be highly flexible and mechanically strong. The fiber rich extensions can be used as flexible interconnects to ancillary circuit members, such as external circuit boards, power or signal sources, and heat sinks.

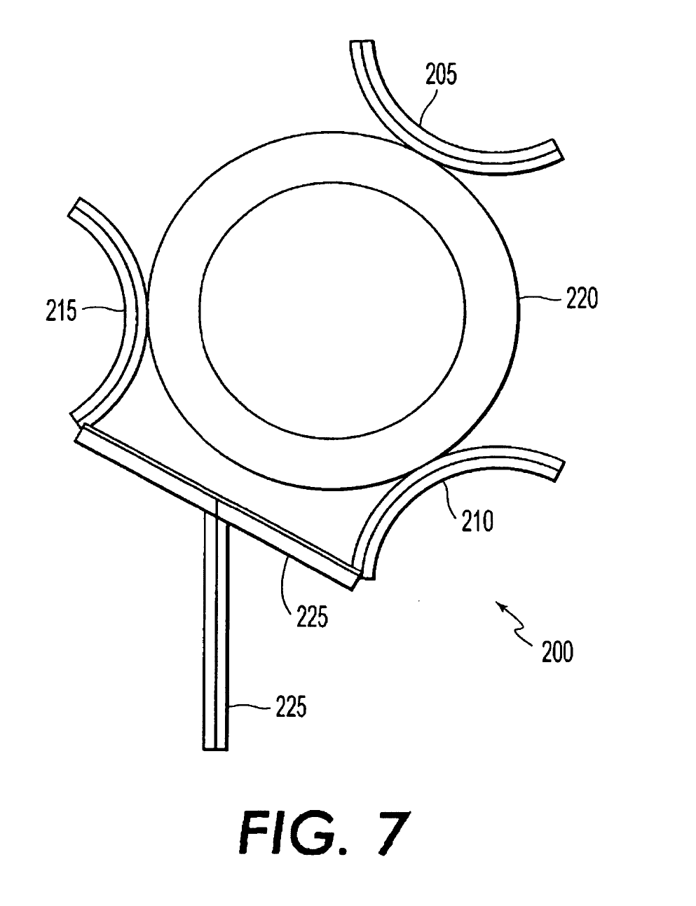

Reference is made to FIG. 7 conducting and non-conducting contact members 205, 210 and 215 are positioned in contact with a shaft member 220 and are mounted in a housing 200. In FIG. 4, the contact members may be positioned in tangential contact with the shaft 220. The housing 200 may be removable to provide serviceability or may be a permanent, or sealed housing member of an integrated assembly.

In FIG. 7, a conducting contact member, e.g., contact members 205, 210, may provide the region for management of electrical power capacity and management of thermal capacity, while another non-conducting contact member, e.g., contact member 215, may provide the contact to provide mechanical load or serve in the location controlling/sensing function, e.g., control or serve to sense the location of the shaft 220 when coupled with an external mechanical sensing element (not shown).

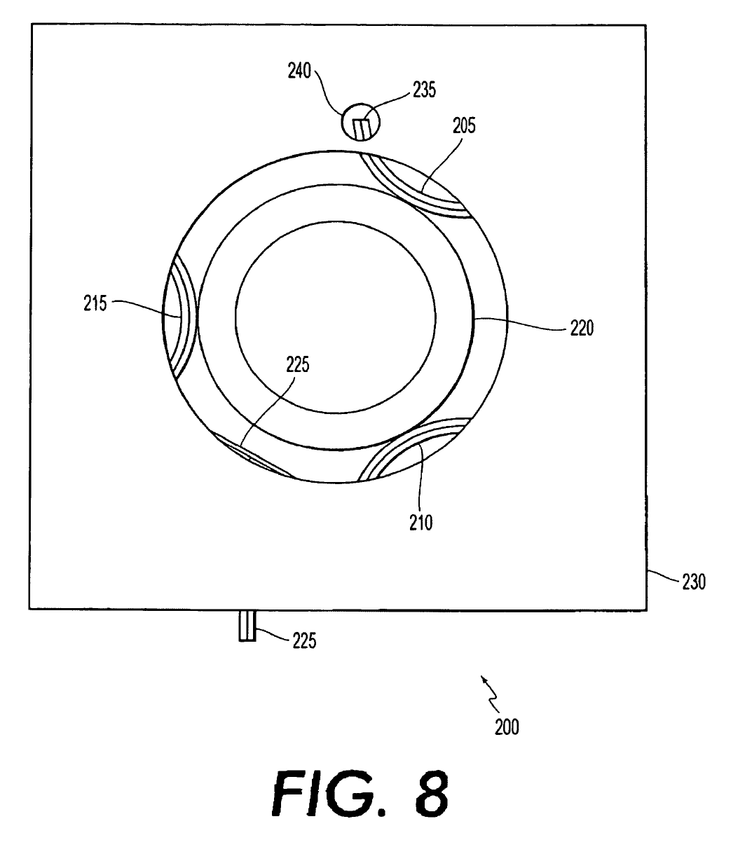

In FIG. 8, the conducting region for management of electrical power capacity, e.g., contact member 205, may be configured to provide direct and temporary contact to a service meter used by a field technician or service representative. For example, the end 235 of the contact member 205 can extend through a hole 240 in the housing 230. A field technician can connect a service meter to the end 235 of the contact member 205 to meter the electrical potential of the contact member. Thus, the end of the sensing electrical contact 235 and/or hole in the housing 230 may act as a test point for a field technician to measure the electrical potential of the shaft 220.

While the above exemplary embodiments have described the contact members 205, 210, 215 as a conductive plastic made of carbon fibers and a host polymer resin, the contact member may include other electronics and/or circuitry. For example, electronics for AC to DC rectification may be included in the contact member. Similarly, resistors, signal processors, filters, capacitors, integrated circuits, e.g. ICs, and diodes, alone or in any combination, may be included within the contact member. Moreover, as discussed below, other materials, such as lubricants, either solid or liquid, may be added to the contact member to provide additional features.

In embodiments, a pultrusion process may be used to make an integrated array of fiber-rich contacts contained within a solid structure where each fiber contained within the individual contact region is a metallized-carbon fiber. The regions separating the contact regions are designed to be electrically insulating and may contain suitable non-conductive fibers or other suitable spacer regions, for example plastic films or tapes, polymeric foams or fiber-based fabrics, and the like. The contact regions within the structure are designed to align on one surface with, for example, the contact pads of an IC chip and with the contact pads of a circuit board on the opposing side. The metallized fibers provide a compliant and low force, reliable, multiple-redundant, low resistance, current path between the device and circuit.

In embodiments, a thin metal layer ranging in thickness from about 0.01 to about 1.5 micron is coated over 6 to 10 micron diameter carbon fibers. The carbon fibers may be a high strength Thornel™ T-300 fiber, a high modulus Thornel™ T-650 fiber, or a low modulus partially carbonized Thornel™ T-150 fiber. Thornel is a tradename of Cytec Carbon Fibers, Inc. Many carbon fibers are commercially available from carbon fiber producers such as Hexcel, Toray, Toho and SGL. The metal layer may be applied by vacuum, vapor, vapor-phase deposition, electroplated, or electroless plated, or a combination of these methods. The metal layer may consist of a single layer or may comprise two or more layers. The metal layer may include various metals or metal alloys. For example, nickel, copper, gold, platinum, tungsten, silver, palladium, tin, iron, aluminum, zinc, chromium, lead, or alloys such as brass, nickel/boron, gold/carbon, palladium/nickel, silver/carbon, and the like, and combinations thereof may be used. The metal layer may consist of a eutectic metal alloy such as tin/lead or similar solder. The conductive fibers may be coated or partially coated with an electrically conductive material, thermally conductive material, and combinations thereof. Metal layers may be applied to the fibers by suppliers such as Conductive Composites of Heber City, Utah.

In embodiments, metalized fibers comprising glass, ceramic, and mineral fibers are envisioned. Similarly, metal fibers having a surface-layer of another metal, such as a Nobel metalized stainless steel fiber, are envisioned.

In embodiments, T-300 type carbon fibers may be packaged at 1,000 filaments per tow and unsized. Vapor deposition of nickel metal to a thickness of V2 to 1 micron corresponding to about 1% to 90% of the weight of the carbon may be applied to the carbon fibers. The metal coating may have a weight in the range of from about 2% to 50% of the weight of the carbon in the pultruded composite conductive member. The nickel metallized carbon may be pultruded in a selected resin binder to form a generally circular 300 micron diameter solid rod shape. The cross-sectional area of a set of bundled fibers may range from about 0.01 square microns to 1000 square microns. A selected number of rods (such as ten rods) may be co-pultruded into a flat 1×10 array of conductive rods separated by insulating resin or by resin and insulating fiber to form a rectangular array with 0.33 mm to 0.50 mm center-to-center spacings. The array may be cut with a suitable CO2 laser to fibrillate the metal-carbon fibers from the binder resin forming an array of resin-free, metal-fiber rich contact regions. One or more of the arrays may be used as an interconnect to contact a device, such as an IC chip along one surface and a circuit board, for example, along the other. The metal may be applied to the carbon-fiber rods or to the individual fibers contained within the rods for a generally low resistance contact. Another option is to also metallize not only the fibers but the external surface of the rods. A further option is to metallize the carbon fiber only at the contact tip regions after laser cutting.

In an embodiment, a thin layer of gold may be vapor deposited onto all of the exposed surfaces of a carbon rich component such as a slip ring regions for management of power capacity and regions for management of thermal capacity as well as non-conductive regions including carbon fibers in MODAR® epoxy modified acrylic resin, available from Ashland Composite Plastics, Dublin, Ohio. The component may be placed in a vacuum-sputtering chamber such as EffaCoater No. 18930, commercially available from Ernest F. Fullam, Inc., Latham, N.Y. After a 50 second argon purge, the chamber may be evacuated to a level less than 100 mTorr. Power (50 mA) may be applied to sputter the gold onto the component. A layer of gold may cover the entire component including the individual fibrillated fibers. A suitable mask can be used to prevent sputtered metal from coating those regions not requiring the metal layer. The gold layer may be continuous and well adhered to the component. The surface conductivity of the component may be increased by about 20× with the addition of the gold coating.

In embodiments, various materials may be configured for use with high frequency (RF) or low energy contacts, regions for management of electrical power capacity and regions for management of thermal capacity as well as non-conductive regions, regions for management of electrical power capacity and regions for management of thermal capacity as well as non-conductive regions bodies, and the like. In embodiments, a pultruded rod, for example, 6 mm diameter, having metalized carbon fibers may be used to carry RF energy. A suitable metal, such as a Nobel metal may be used. The metal coating of the fibers enables RF energy to be carried efficiently along the fibers' surfaces and the fibers within the structure generally improves its strength while providing for thermal conduction pathways should the application require. A rod or tube shaped structural member may be used for an RF contact or regions for management of electrical power capacity and regions for management of thermal capacity as well as non-conductive regions including metallized carbon fibers pultruded in a suitable binder resin, such as MODAR® modified acrylic. A laser may be used to fibrillate fibers and to drill-form holes into the rod or tube or elbow to mate with other conventional contacting devices such as metal pin regions for management of electrical power capacity and regions for management of thermal capacity as well as non-conductive regions. Alternately, a rod or tube or elbow shaped member may be selectively metallized on the internal surfaces, external surfaces or both. For large, tubular shapes that are used as regions for management of electrical power capacity and regions for management of thermal capacity as well as non-conductive regions bodies in RF regions for management of power capacity and regions for management of thermal capacity as well as non-conductive regions, for example, resin transfer molding, pre-preg winding, and or layer-composite laminate molding may be used instead of pultrusion. Internal or external surface features (such as ring grooves, recesses, wells, slots, holes, threads, and the like) may be incorporated into the structure without the need for secondary machining operation and without interruption of the skin-layer conduction mechanisms.

In embodiments, conductive pultruded composite member may extend from the region as a substrate at a first side and from the region as a substrate at a second side for a selected distance and are adapted for contact; the conductive pultruded composite regions and the non-conductive regions may be disposed in more than one plane and be situated offset from each other; the apparatus having regions and regions may be used for establishing a permanent electrical circuit with at least one other element such as a circuit, integrated circuit, component or assembly; the apparatus having management of electrical power capacity regions and management of thermal capacity regions may be used for establishing a temporary electrical circuit; the apparatus having management of electrical power capacity regions and management of thermal capacity regions may be used for testing of a separable circuit; the apparatus having management of electrical power capacity regions and management of thermal capacity regions may be used for testing of a removeably securable circuit in association therewith; a circuit may be securable to at least a portion of the apparatus having management of electrical power capacity regions and management of thermal capacity regions; the at least one conductive pultruded composite regions and the at least one non-conductive regions may each include a longitudinal axis situated in the region as a substrate substantially parallel to one another; at least one conductive pultruded composite member may include a first surface area and a second surface area exposed for conduction of energy therethrough; the energy may be selected from at least one of electric and thermal; the at least one conductive pultruded composite member may include a fibrillated portion having a length in the range from 0.001 mm to 1000 mm; the at least one conductive pultruded composite member may include a first end and a second end and at least a portion of the first end and the second end are fibrillated and for establishing a circuit that is permanent; at least one conductive pultruded composite regions may be accessible along its length to provide a conductive surface area for contact; each of the conductive fibers may have a thickness in the range from 0.001 microns to 1 millimeter; a conductive fiber region area as a percent of the substrate member region area may range from 0.005% to 99.5% by volume; at least one additional substrate member region may include at least one conductive pultruded composite regions including at least one conductive fibers having a length and at least one non-conductive regions having a length including at least one of a non-conductive fiber and a non-conductive resin; and a pultruded conductive composite member may have a length and a diameter in the range of from 1 micron to 2 meters. The conductive pultruded composite regions and the non-conductive regions form a selected matrix configuration. The substrate member regions are adapted for adjacent association and form an array of selected dimension dependent on the number of region as a substrate regions; the selected matrix configuration may include a non-conductive region separated from another non-conductive region; the selected matrix configuration may include a conductive fiber region situated adjacent a non-conductive fiber region; the substrate member region may include a polymer; an average distance between the center of the conductive fiber regions may range from 1.001 to 10,000 times greater than the area of the largest conductive fiber region; an average distance between the conductive fiber regions may range from 0.0011 microns to 1 meter; the surface area measured on an outside perimeter of the substrate member region may range from 0.01 square millimeters to 10 square meters; the conductive fibers may include at least one of carbonized polyacrylonitrile fibers, carbonized pitch fibers, carbonized polybenzimidazole (PBI) fibers, metalized carbon fibers, metalized ceramic fibers, metalized glass fibers, metalized mineral fibers, metal fibers, carbon nano tubular fibers, and combinations thereof; each fiber may be generally circular in cross section and have a diameter range of from 0.5 nanometers to 250 micrometers; the fibers may have a DC volume resistivity of from 1×10⁻⁶ ohm-cm to 1×10⁺¹⁵ ohm-cm, the substrate member region may include at least 0.001% by weight conductive fibers; the apparatus having regions and regions may be used for voltages ranging between 1×10⁻¹² volts and greater than 10⁺⁶ volts and currents ranging between 10⁻⁹ amps and 10⁺⁶ amps and at least one of direct current or frequencies up to 200 gigahertz; the apparatus having regions and regions may be suitable for use in an RF electric circuit to conduct alternate current in the range of 1 hertz to 200 giga-hertz; the member may include from 1 to 1×10⁺¹⁰ point contacts per cm2; the polymer may be selected from at least one of structural thermoplastic, thermosetting resin, and crosslinked silicone elastomer; the resin may be selected from at least one of a polyester, vinyl ester, polyethersulphone, polyetheretherketone, polyetherimide, polyimide, polyamide, polyacrylic, epoxy-modified acrylic, phenolic, epoxy, copolymers, and combinations thereof; the apparatus having regions and regions may include at least one region as a substrate regions associated with one another such that the conductive and non-conductive pultruded regions extend in substantially the same direction; an end of at least one of the conductive pultruded composite regions may include a flexible or spring-like fibrillated region exposed on the apparatus having regions and regions; an end of at least one of the conductive pultruded composite regions may include a hard, non-fibrillated region; the fibrillated region may include at least one conductive fibers; an end of at least one of the conductive pultruded composite regions may include a shaped profile selected from at least one of rectangular, square, stepped, concave dome, convex recess, concave point, angular, and irregular; and combinations thereof; the apparatus having management of electrical power capacity regions and management of thermal capacity regions may include at least one non-conductive regions comprising non-conductive fibers; the management of electrical power capacity regions and management of thermal capacity regions and the non-conductive regions may be pultruded composite regions; the conductive contact area may be adapted to associate with an electronic component or an integrated circuit to provide continuity from the at least one conductive member on one side of the recess, across the at least one recess, and to the at least one conductive member on the other side of the recess; the conductive fibers may be carbon fibers, metalized carbon fibers, metalized glass fibers, metalized polymeric fibers, metalized mineral fibers, metalized ceramic fibers, carbon or carbon nanotube particle filled polymeric fibers, metal particle filled polymeric fibers, intrinsically conducting polymeric fibers, fine metal wires, or combinations thereof; the conductive contact area may be adapted to associate thermally and mechanically as well as electrically with an electronic component to provide an electromechanical contact; and the non-conductive area may be adapted to associate mechanically with an electronic component to provide a contact structure having combined electro-, thermal- and mechanical features.

In embodiments, the apparatus having at least one conductive region having management of electrical power capacity regions and at least one conductive region having management of thermal capacity regions and the at least one non-conductive regions or conductive member may not be straight along its length and may extend in more than one direction. The member may include a lumen. The lumen including an opening to permit the passage of light or air. The member may include an opening or bore in a tube. The member may be a rod or a tube. The member may include a cavity. The member may include an opening in a wall between the interior and exterior periphery surfaces. The inner wall or walls of the tube region optionally having a metal layer applied thereon. The conductive region may be for communication with a circuit. The conductive region may be exposed at a periphery surface. At least one conductive fiber may be at least partially coated with an electrically conductive material. The conductive region may be at least partially coated with an electrically conductive material. The conductive regions may include a thermally conductive material. The coating layer may be formed by at least one of vacuum deposition, vapor deposition, electroplated, sputter coating, and electroless plated process. The conductive material may be a metal or metal alloy. The conductive material may include at least one of nickel, copper, gold, platinum, tungsten, silver, palladium, tin, iron, aluminum, zinc, chromium, lead, brass, nickel/boron, gold/carbon, palladium/nickel, and silver carbon. The metal may be a eutectic metal alloy including tin/lead and solder. The conductive fibers are carbon and the metal coating may have a weight in the range of from 2% to 50% of the weight of the carbon fiber and the metalized fiber may have a weight in the range of 0.001 to 98% of the pultruded conductive composite member. The conductive region may be within 25 microns of at least one of the exterior periphery surface and the interior periphery surface. The at least one carbon fiber may be metal coated and pultruded in a resin binder to form a cross-sectional shape that comprises a metal coating wherein the coating has a weight in the range of from 1% to 90% of the weight of the pultruded conductive composite member. The at least one carbon fiber may be metal coated and separated from another by at least one of a resin binder and insulating fiber. At least one conductive fiber may be bundled together forming at least one set of conductive fibers, the at least one set of conductive fibers having a length and cross sectional area in the range of from less than 0.01 square microns to 10000 square microns wherein a metal coating having a thickness is disposed on at least a portion of an outside surface of the at least one set of conductive fibers. Fibrillated fibers may extend from a surface. The fibrillated region may have a length in the range from 0.001 mm to 1000 mm and be substantially flexible. The fibrillated region may be composited with an elastomer. The fibrillated region may include an exposed at least one conductive fiber extending from the member. The apparatus having at least one conductive region having management of electrical power capacity regions and at least one conductive region having management of thermal capacity regions and the at least one non-conductive regions may be suitable for use in an RF electric circuit to conduct current in the range of 1 hertz to 200 giga-hertz.

### Non-Limiting Embodiments

1. An apparatus comprising:
a substrate member region including a length, a width, a thickness, and a surface area, the substrate member region including a host binder material selected from the group consisting of a polymer, a thermal plastic polymer, a thermo setting polymer, an intrinsically conductive polymer, an elastomer, a ceramic, a glass, a cement, a cermet, a metal, a synthetic metal, combinations and mixtures of the above, at least one conductive region having management of electrical power capacity regions and at least one conductive region having management of thermal capacity regions and at least one non-conductive region, each of the conductive regions and the non-conductive regions have a length and an imaginary axis; wherein the at least one conductive region having management of electrical power capacity regions and at least one conductive region having management of thermal capacity regions comprises at least one conductive fibers and a polymer material, the at least one conductive fibers configured in a relation to each other and in association with the polymer material; wherein the at least one conductive region having management of electrical power capacity regions and at least one conductive region having management of thermal capacity regions and the at least one non-conductive regions are disposed in the substrate member region and are situated with respect to each other and form a matrix configuration including at least one dimension between the imaginary axis of the at least one conductive region having management of electrical power capacity regions and at least one conductive region having management of thermal capacity regions and including at least one dimension between the imaginary axis of the at least one non-conductive regions; wherein at least one non-conductive member is situated between at least two conductive regions; wherein the conductive regions and the non-conductive regions are in a defined relation in the substrate member region; wherein the polymer of the substrate member region is solidified about at least a portion of a periphery of the at least one conductive region having management of electrical power capacity regions and at least one conductive region having management of thermal capacity regions and is solidified about at least a portion of a periphery of the at least one non-conductive regions forming an integral structure; and wherein at least one conductive member includes an exposed surface for contact, wherein the apparatus is a component of a system selected from the group consisting of human carryable firearms, weaponry and large armaments, exoskeletons, robotics, electromechanical systems (EMS), transportation systems, missiles, radomes, telecommunications, antennae tower, antennae, electronic systems, energy applications such as wind turbines, hydro turbines, microbial fuel cell, waste treatment, water purification, defribilators, intrabody implants, smart tooling, smart machining, orthotics, avionics, and avionics integrated into air frames.
2. The apparatus of embodiment 1, wherein the at least one conductive region having management of electrical power capacity regions and the at least one conductive region having management of thermal capacity regions and the non-conductive regions are pultruded composite regions.
3. The apparatus of embodiment 1, wherein at least one conductive region having management of electrical power capacity regions and at least one conductive region having management of thermal capacity regions extends from the region as a substrate at a first side and from the region as a substrate at a second side for a distance.
4. The apparatus of embodiment 1, wherein the exposed surface includes fibers unbound and substantially free of the host binder material.
5. The apparatus of embodiment 1 wherein the at least one conductive region having management of electrical power capacity regions and at least one conductive region having management of thermal capacity regions and the at least one non-conductive regions are disposed in more than one plane.
6. The apparatus of embodiment 1 wherein the apparatus having at least one conductive region having management of electrical power capacity regions and at least one conductive region having management of thermal capacity regions and the at least one non-conductive regions is adapted for association with at least one element and an electrical circuit.
7. The apparatus of embodiment 1 wherein the apparatus is adapted for association with at least one element and a temporary electrical circuit wherein the at least one element is removeably securable to the apparatus having at least one conductive region having management of electrical power capacity regions and at least one conductive region having management of thermal capacity regions and the at least one non-conductive regions.
8. The apparatus of embodiment 1 further comprising an integrated circuit wherein the integrated circuit is securable to at least a portion of the apparatus having at least one conductive region having management of electrical power capacity regions and at least one conductive region having management of thermal capacity regions and the at least one non-conductive regions.
9. The apparatus of embodiment 1 further comprising a die wafer having individual integrated circuit chips wherein the die wafer is securable to at least a portion of the apparatus having at least one conductive region having management of electrical power capacity regions and at least one conductive region having management of thermal capacity regions and the at least one non-conductive regions.
10. The apparatus of embodiment 1, wherein at least one conductive region selected from the group consisting of at least one conductive region having management of electrical power capacity regions and at least one conductive region having management of thermal capacity regions and the at least one non-conductive regions includes a first surface area and a second surface area exposed for conduction of energy therethrough wherein the energy is selected from at least one of electric capacity and thermal capacity.
11. The apparatus of embodiment 1, wherein the imaginary axis of at least one of the conductive regions selected from the group consisting of at least one conductive region having management of electrical power capacity regions and at least one conductive region having management of thermal capacity regions and the non-conductive regions includes a form selected from the group consisting of substantially straight, angled, and curved.
12. The apparatus of embodiment 1 having at least one conductive region having management of electrical power capacity regions and at least one conductive region having management of thermal capacity regions and at least one non-conductive region, wherein at least one conductive member includes at least one conductive fiber selected from the group consisting of carbon fibers, carbonized polyacrylonitrile fibers, carbonized pitch fibers, carbonized polybenzimidazoles (PBI) fibers, graphite fibers, carbonized natural fiber, carbonized mineral, carbon nanotubes, carbon nanotubes filled polymeric fibers, carbon filled polymeric fibers, metalized mineral fibers, metalized carbon fibers, metal fibers, metal alloy fibers, metalized glass, metalized ceramic, metalized metal, metalized synthetic metal, metalized polymer, and combinations thereof.
13. The apparatus of embodiment 1 having at least one conductive region having management of electrical power capacity regions and at least one conductive region having management of thermal capacity regions and the at least one non-conductive regions, wherein at least one conductive member is accessible along at least a portion of its length to provide a conductive surface area for contact.
14. The apparatus of embodiment 1 having at least one conductive region having management of electrical power capacity regions and at least one conductive region having management of thermal capacity regions and the at least one non-conductive regions wherein an area of the conductive member as a percent of an area of the substrate member region ranges from 0.001% to 99.5%.
15. The apparatus of embodiment 1 further comprising at least one additional substrate member region, the at least one additional substrate member region including: (a) at least one conductive regions comprising at least one conductive fibers, the conductive regions having a length; and (b) at least one non-conductive regions comprising at least one of a non-conductive fiber and a non-conductive resin, the non-conductive regions having a length, the conductive regions and the non-conductive regions forming a matrix configuration; wherein the at least one additional substrate member region is adapted for functional association with the other substrate member region and defining an array of region as a substrate regions including a configuration dependent on the selected number of region as a substrate regions.
16. The apparatus of embodiment 1 having at least one conductive region having management of electrical power capacity regions and at least one conductive region having management of thermal capacity regions and the at least one non-conductive regions wherein the substrate member region comprises a host binder material selected from at least one of thermoplastic resin, thermosetting resin, an elastomer, ceramic, glass, cermet, and concrete.
17. The apparatus of embodiment 1 wherein the conductive fibers are selected from the group consisting of carbon, carbonized polyacrylonitrile fibers, carbonized pitch fibers, carbonized polybenzimidazoles (PBI) fibers, carbonized natural fiber, carbonized mineral, carbon nanotubes, metalized mineral fibers, metalized carbon fibers, and combinations thereof.
18. The apparatus of embodiment 1 having at least one conductive region having management of electrical power capacity regions and at least one conductive region having management of thermal capacity regions and at least one non-conductive regions of wherein the conductive fibers include at least one of metal, metal alloy, glass, metalized glass, ceramic, metalized ceramic, metalized ceramic, metalized metal, metalized synthetic metal, metalized polymer, optically transmissive polymer, and combinations thereof.
19. The apparatus of embodiment 15 wherein the array of the region as a substrate regions is adapted to be assembled into a configuration by lamination, adhesive bonding, ultrasonic or other welding process, by mechanical fastening or interlocking, or combinations thereof.
20. An apparatus comprising:
a substrate member region having a material selected from the group consisting of a polymer, a thermal plastic polymer, a thermo setting polymer, an intrinsically conductive polymer, an elastomer, a ceramic, a glass, a cement, a metal, a synthetic metal, combinations and mixtures of the above, the substrate member region including: a length; a width; and a thickness;
at least one conductive pultruded composite region selected from the group consisting of at least one conductive region having management of electrical power capacity regions and at least one conductive region having management of thermal capacity regions including at least one conductive fibers and a polymer material, the at least one conductive pultruded composite region having conductive fibers configured in a relation to each other and in association with the polymer material, each conductive pultruded composite member having a first end and a second end; and at least one non-conductive regions including at least one non-conductive fibers, each non-conductive member having a first end and a second end;
wherein the at least one conductive pultruded composite regions and the at least one non-conductive regions are disposed in the substrate member region and are situated with respect to each other and form a matrix configuration including at least one dimension between the imaginary axis of at least one conductive pultruded composite regions and including at least one dimension between the imaginary axis of at least one non-conductive regions; wherein at least one non-conductive member is disposed between at least one pair of conductive regions defining a spatial relation between the at least one conductive regions and the at least one non-conductive regions in the matrix configuration; wherein the conductive regions and the non-conductive regions are in a non-woven relation in the substrate member region wherein the polymer of the substrate member region is solidified about at least a portion of a periphery of the at least one conductive pultruded composite regions and is solidified about at least a portion of a periphery of the at least one non-conductive regions forming an integral structure; and wherein at least one conductive pultruded composite member is accessible at the first end and the second end for contact.
21. The apparatus of embodiment 20 having at least one conductive region having management of electrical power capacity regions and at least one conductive region having management of thermal capacity regions and the at least one non-conductive regions, wherein at least one of the conductive pultruded composite regions includes a flexible fibrillated region.
22. The apparatus of embodiment 20 having at least one conductive region having management of electrical power capacity regions and at least one conductive region having management of thermal capacity regions and the at least one non-conductive regions wherein at least one of the conductive pultruded composite regions includes a hard, non-fibrillated region.
23. The apparatus of embodiment 20 having wherein at least one of the conductive pultruded composite regions includes a shaped profile, the shaped profile selected from at least one of rectangular, square, stepped, concave dome, convex dome, concave point, convex recess, angular, and irregular.
24. The apparatus of embodiment 20 having at least one conductive region having management of electrical power capacity regions and at least one conductive region having management of thermal capacity regions and the at least one non-conductive regions wherein the substrate member region includes a recessed area.
25. The apparatus of embodiment 20 having at least one conductive region having management of electrical power capacity regions and at least one conductive region having management of thermal capacity regions and the at least one non-conductive regions wherein the substrate member region includes at least one conductive pultruded composite regions extending in at least one longitudinal directions in more than one plane.
26. An apparatus having at least one conductive region having management of electrical power capacity regions and at least one conductive region having management of thermal capacity regions and the at least one non-conductive regions comprising:
a substrate member region comprising a polymer, the substrate member region having a length, width, and thickness;
at least one conductive regions having a first end, second end, and length, the at least one conductive regions comprising at least one conductive fibers extending in the substrate member region;
at least one continuity break defining an interruption along the length of at least one conductive member between the first end and the second end of the at least one conductive member, wherein the at least one continuity break is defined by a recess formed in the substrate member region and absence of at least a portion of the at least one conductive member;
at least one conductive contact area is associated with at least one conductive member on one side of the at least one continuity break, and at least one conductive contact area is associated with at least one conductive member on the other side of the at least one continuity break;
wherein the at least one conductive regions are disposed in the substrate member region and are situated with respect to each other and form a matrix configuration including at least one dimension between the imaginary axis of at least one conductive regions; wherein the polymer of the substrate member region is solidified about at least a portion of a periphery of the at least one conductive regions forming an integral structure.
27. The apparatus having at least one conductive region having management of electrical power capacity regions and at least one conductive region having management of thermal capacity regions and the at least one non-conductive regions of embodiment 26, wherein the at least one recess includes a width, depth, and extends in the substrate member region.
28. The apparatus having at least one conductive region having management of electrical power capacity regions and at least one conductive region having management of thermal capacity regions and the at least one non-conductive regions of embodiment 26, wherein the apparatus having at least one conductive region having management of electrical power capacity regions and at least one conductive region having management of thermal capacity regions and the at least one non-conductive regions further includes at least one non-conductive regions comprising non-conductive fibers.
29. The apparatus having at least one conductive region having management of electrical power capacity regions and at least one conductive region having management of thermal capacity regions and the at least one non-conductive regions of embodiment 28, wherein at least one of the conductive regions and the non-conductive regions are pultruded composite regions.
30. The apparatus having at least one conductive region having management of electrical power capacity regions and at least one conductive region having management of thermal capacity regions and the at least one non-conductive regions of embodiment 26, wherein the at least one conductive contact area is adapted to associate with at least one of an integrated circuit and an electronic component to provide continuity from the at least one conductive member on one side of the at least one continuity break, across the at least one continuity break, and to the at least one conductive member on the other side of the at least one continuity break.
31. The apparatus having at least one conductive region having management of electrical power capacity regions and at least one conductive region having management of thermal capacity regions and the at least one non-conductive regions of embodiment 26, wherein an end of at least one conductive member extends from the region as a substrate.
32. The apparatus having at least one conductive region having management of electrical power capacity regions and at least one conductive region having management of thermal capacity regions and the at least one non-conductive regions of embodiment 26, wherein the at least one conductive regions includes exposed fibrillated fibers.
33. The apparatus having at least one conductive region having management of electrical power capacity regions and at least one conductive region having management of thermal capacity regions and the at least one non-conductive regions of embodiment 26, wherein the at least one conductive regions includes fibrillated fibers contained in a flexible resin or sheath.
34. The apparatus having regions and regions of embodiment 26, wherein the at least one conductive composite regions include conductive fibers comprising at least one of carbon fibers, metallized carbon fibers, metallized glass fibers, metallized polymeric fibers, carbon particle filled polymeric fibers, metal particle filled polymeric fibers, intrinsically conducting polymeric fibers, fine metal wires, and combinations thereof.
35. The apparatus having at least one conductive region having management of electrical power capacity regions and at least one conductive region having management of thermal capacity regions and the at least one non-conductive regions of embodiment 26, wherein the substrate member region comprises at least one conductive member including a first surface area on one side of the at least one continuity break and a second surface area on the other side of the of the at least one continuity break exposed for conduction of energy therethrough wherein the energy is selected from at least one of electric, thermal, sound, sonic, and light energy.
36. The apparatus having at least one conductive region having management of electrical power capacity regions and at least one conductive region having management of thermal capacity regions and the at least one non-conductive regions of embodiment 26, wherein the at least one conductive contact area is adapted to associate mechanically, thermally, and electrically with an electronic component to provide an electro-mechanical contact.
37. The apparatus having at least one conductive region having management of electrical power capacity regions and at least one conductive region having management of thermal capacity regions and the at least one non-conductive regions of embodiment 26, wherein at least one non-conductive area is adapted to associate mechanically with an electronic component to provide a mechanical contact structure.
38. An apparatus comprising:
a management of electrical power capacity regions and a management of thermal capacity regions, the apparatus having a substrate member region having a length, a width, a thickness, and a surface area, the substrate member region including a host binder material selected from the group consisting of a polymer, a thermal plastic polymer, a thermo setting polymer, an intrinsically conductive polymer, an elastomer, a ceramic, a glass, a cement, a cermet, a metal, a synthetic metal, combinations and mixtures of the above and the like, the substrate member region including at least one conductive region for management of electrical power capacity and at least one conductive region for management of thermal capacity and at least one non-conductive regions, each of the conductive regions for management of electrical power capacity and conductive regions for management of thermal capacity as well as the non-conductive regions has a length and an imaginary axis, the at least one conductive region for management of electrical power capacity and at least one conductive region for management of thermal capacity and optionally the non-conductive regions comprises at least one fiber and a host resin material, the fibers contained within the at least one electrical conducting region for management of electrical power capacity and the at least one conducting region for management of thermal capacity as well as non-conductive region fibers are configured in a relation to each other and in association with the host resin material such that the region for management of electrical power capacity and the at least one region for management of thermal capacity as well as the at least one non-conductive region are disposed in the substrate member and are selectively situated with respect to each other and may, in certain embodiments, form a matrix configuration including at least one selected dimension between the imaginary axis of the at least one region for management of electrical power capacity or at least one selected dimension between the imaginary axis of the at least one region for management of thermal capacity as well as at least one selected dimension between an imaginary axis of the at least one non-conductive region and including at least one selected dimension between the imaginary axis of the at least one non-conductive regions.
39. The apparatus of embodiment 38 wherein the polymer of the substrate member is solidified about at least a portion of a periphery of the at least one region for management of electrical power capacity or at least a portion of a periphery of the at least one region for management of thermal capacity as well as non-conductive regions and is solidified about at least a portion of a periphery of the at least one non-conductive regions forming an integral structure.
40. The apparatus of embodiment 39 wherein at least one of the regions for management of electrical power capacity and, optionally, at least one of the regions for management of thermal capacity as well as non-conductive regions includes an exposed surface for contact with another surface of a functional device, for example a surface mounted accessory requiring transfer of electric or thermal energy.
41. An apparatus comprising: a substrate member having a length, a width, a thickness; the substrate member comprising a material selected from the group consisting of a polymer, a thermal plastic polymer, a thermo setting polymer, an intrinsically conductive polymer, an elastomer, a ceramic, a glass, a cement, a cermet, a metal, a synthetic metal, combinations and mixtures of the above and the like; at least one conducting region selected from the group consisting of a pultruded region, a mold formed region, an extruded forms region, a lay-up forms region; wherein the at least one conducting region is designed for management of electrical power capacity or for management of thermal capacity, and at least one non-conductive regions.
42. The apparatus of embodiment 41 wherein at least one region for management of electrical power capacity or at least one region for management of thermal capacity may include pultruded composite regions including at least one conductive carbon fibers and a polymer material such as polyester, polyimide, nylon, epoxy and the like.
43. The apparatus of embodiment 42 wherein the at least one conductive carbon fiber is configured in a relation to other fibers and in association with the polymer material.
44. The apparatus of embodiment 42 wherein each region for management of electric power capacity and region for management of thermal capacity has a first end and a second end.
45. The apparatus of embodiment 44 wherein the at least one non-conductive region includes at least one non-conductive fiber, each non-conductive region having a first end and a second end, wherein the at least one region for management of electrical power capacity and regions for management of thermal capacity as well as non-conductive regions are disposed in the apparatus substrate member region and are selectively situated with respect to each other and may, in certain embodiments, form a matrix configuration including at least one selected dimension between the imaginary axis of at least one region for management of power capacity or regions for management of thermal capacity as well as non-conductive pultruded composite regions and including at least one selected dimension between the imaginary axis of the non-conductive regions.
46. The apparatus of embodiment 45 wherein the polymer of the substrate member region is solidified about at least a portion of a periphery of the at least one region for management of electrical power capacity or about at least a portion of a periphery of the at least one region for management of thermal capacity as well as non-conductive regions and is solidified about at least a portion of a periphery of the at least one non-conductive region forming an integral structure.
47. The apparatus of embodiment 4 wherein at least one region for management of electrical power capacity or one region for management of thermal capacity is accessible at a portion of the substrate member for contact with an electric power source or heat source or a power- or heat-requiring member.
48. An apparatus comprising: at least one conductive fiber blended with a host polymer by an extrusion process to create regions for management of electrical power capacity and regions for management of thermal capacity and a substrate member region including a length, a width, a thickness; the substrate member region having a thermal plastic polymer, and at least one region for management of electrical power capacity and at least one region for management of thermal capacity as well as non-conductive regions.
49. The apparatus of embodiment 48 wherein the at least one region for management of electrical power capacity and/or at least one region for management of thermal capacity as well as non-conductive regions, each region having a first end, a second end, and a length.
50. The apparatus of embodiment 51 further including at least one region for management of electrical power capacity and at least one region for management of thermal capacity as well as non-conductive regions, each of the regions including fibers extending in the regions.
51. The apparatus of embodiment 50 further comprising regions each being integrated into a substrate member region.
52. The apparatus of embodiment 51 wherein at least one region for management of electrical power and/or management of thermal capacity may be disposed in a substrate member and are selectively situated with respect to each other and may form a geometric configuration including at least one selected dimension between the imaginary axis of at least one region for management of electrical power and/or management of thermal capacity; wherein the polymer of the substrate member region is solidified about at least a portion of a periphery of the at least one region for management of electrical power and/or management of thermal capacity forming an integral structure.
53. An apparatus comprising: regions for management of electrical power capacity and regions for management of thermal capacity as well as non-conductive regions; the apparatus may be used in the electronics industry, for such applications as, e.g., integrated circuits, test systems, electrical systems, power and signal circuitry and in association with systems such as, for example, electrical test equipment, communications equipment, computers and peripherals, analog or digital systems including audio and video transmission and reproduction systems.
55. Any combination or single embodiment of embodiments 1-54 in combination with any combination or single embodiment of embodiments 1-54 without regard for the numerical ordering of the embodiments.

It is appreciated that various other alternatives, modifications, variations, improvements, equivalents or substantial equivalents of the teachings herein that for example, are or may be presently unforeseen, unappreciated or subsequently arrived at by applicants or others are also intended to be encompassed by the claims and amendments thereto.

What is claimed is:

1. An apparatus comprising:
a substrate member having a length, a width, a thickness;
the substrate member comprising a material selected from the group consisting of a polymer or intrinsically conductive polymer selected from the group consisting of polyethylene, polypropylene, polystyrene, polyvinylchloride, nylon, polyester, polyimide, polyphenelyene sulfide, poly ether ether ketone, polyimideamide, polyetherimide, polyurethane, vinyl ester, epoxy, polyvinyls, poly-cellulose derivatives, fluoroelastomers, polysiloxanes, polysilanes, polycarbazoles, polyphenothiazines, polyetherketones, polyetherimides, polyethersulphones, polyurethanes, polyether urethanes, polyester urethanes, polytetrafluoroethylenes, polycarbonates, polyacrylonitriles, poly(ester-imides), polyfluoroalkoxys, poly(amide-imides), polymers synthesized from a methyl methacrylate monomer and a bisphenol monomer, polyacetylene, polyphenylene vinylene, polypyrrole, polythiophene, polyaniline, polyphenylene sulfide, and copolymers and mixtures thereof, an elastomer, a ceramic, a glass, a cement, a cermet, a metal, a synthetic metal, and combinations and mixtures of any of the above materials;
at least one conducting region selected from the group consisting of a pultruded region, a mold formed region, an extruded region, a lay-up formed region; wherein the at least one conducting region is designed for management of electrical power capacity, management of thermal capacity and at least one non-conductive region.

2. The apparatus of claim 1 wherein the at least one region for management of electrical power capacity or the at least one region for management of thermal capacity may include pultruded composite regions including at least one conductive carbon fibers and a polymer material, such as polyester, polyimide, nylon, epoxy and the like.

3. The apparatus of claim 2 wherein the at least one conductive carbon fiber is configured in a specific relation to other fibers and in specific association with the polymer material.

4. The apparatus of claim 1 wherein each region for management of electric power capacity and region for management of thermal capacity has a first end and a second end.

5. The apparatus of claim 3 wherein the at least one non-conductive region includes at least one non-conductive fiber, each non-conductive region having a first end and a second end, wherein the at least one region for management of electrical power capacity and regions for management of thermal capacity as well as non-conductive regions are disposed in the apparatus substrate member region and are selectively situated with respect to each other and form a matrix configuration including at least one selected dimension between the imaginary axis of at least one region for management of power capacity or regions for management of thermal capacity as well as non-conductive pultruded composite regions and including at least one selected dimension between the imaginary axis of the non-conductive regions.

6. The apparatus of claim 5 wherein the material of the substrate member region is solidified about at least a portion of a periphery of the at least one region for management of electrical power capacity or about at least a portion of a periphery of the at least one region for management of thermal capacity as well as non-conductive regions and is solidified about at least a portion of a periphery of the at least one non-conductive region forming an integral structure.

7. The apparatus of claim 5 wherein at least one region for management of electrical power capacity or one region for management of thermal capacity is accessible at a portion of the substrate member for contact with an electric power source or heat source or a power- or heat-requiring member.

8. An apparatus comprising:
at least one conductive fiber blended with a host polymer by an extrusion process to create regions for management of electrical power capacity and regions for management of thermal capacity;
and a substrate member region including a length, a width, a thickness; the substrate member region having a thermal plastic polymer and at least one region for management of electrical power capacity and at least one region for management of thermal capacity as well as non-conductive regions.

9. The apparatus of claim 8 wherein the at least one region for management of electrical power capacity and/or at least one region for management of thermal capacity as well as non-conductive regions, each region having a first end, a second end, and a length.

10. The apparatus of claim 9 further including at least one region for management of electrical power capacity and at least one region for management of thermal capacity as well as non-conductive regions, each of the regions including fibers extending in the regions.

11. The apparatus of claim 10 further comprising conductive and non-conductive regions each being integrated into the substrate member region.

12. The apparatus of claim 11 wherein the at least one region for management of electrical power and/or management of thermal capacity are disposed in a substrate member and are selectively situated with respect to each other to form a geometric configuration including at least one selected dimension between the imaginary axis of at least one region for management of electrical power and/or management of thermal capacity; wherein the polymer of the substrate member region is solidified about at least a portion of a periphery of the at least one region for management of electrical power and/or management of thermal capacity forming an integral structure.

13. The apparatus of claim 12 to be used in the electronics industry, for such applications as, e.g., integrated circuits, test systems, electrical systems, power and signal circuitry and in association with systems such as, for example, electrical test equipment, communications equipment, computers and peripherals, analog or digital systems including audio and video transmission and reproduction systems.

14. The apparatus of claim 1 wherein:
the regions for management of power capacity or regions for management of thermal capacity are first pultruded to form a conductive pultruded composite member and then this pre-pultrusion is added to the non-conductive regions to form a final pultruded matrix;
the regions for management of power capacity or regions for management of thermal capacity are first co-pultruded to provide the regions for management of power capacity and regions for management of thermal capacity and non-conductive fibers are properly aligned and spaced in relation to the co-pultruded regions for management of power capacity and regions for management of thermal capacity of to provide a final composite pultruded configuration;
pre-pultrude the non-conductive regions into a pre-pultrusion and then combine this with the regions for management of power capacity and regions for management of thermal capacity to create a final matrix; or, pre-pultrude individually each of the regions for management of power capacity and regions for management of thermal capacity and non-conductive regions and then co-pultrude these into a final matrix. In addition, other compositing techniques such as resin transfer molding, insert molding, rotary molding, and or layer-composite laminate molding may be used instead of pultrusion.

15. The apparatus of claim 1 wherein:
the method of forming the regions for management of power capacity, regions for management of thermal capacity and non-conductive regions is selected from the group consisting of compression molding, resin transfer molding, filament winding, injection molding, sheet molding, laminating processes and combinations thereof in any order of method steps.

16. The apparatus of claim 15 wherein each region for management of electric power capacity and region for management of thermal capacity has a first end and a second end.

17. The apparatus of claim 16 wherein the at least one non-conductive region includes at least one non-conductive fiber, each non-conductive region having a first end and a second end, wherein the at least one region for management of electrical power capacity and regions for management of thermal capacity as well as non-conductive regions are disposed in the apparatus substrate member region and are selectively situated with respect to each other and form a matrix configuration including at least one selected dimension between the imaginary axis of at least one region for management of power capacity or regions for management of thermal capacity as well as non-conductive pultruded composite regions and including at least one selected dimension between the imaginary axis of the non-conductive regions.

18. The apparatus of claim 17 wherein the material of the substrate member region is solidified about at least a portion of a periphery of the at least one region for management of electrical power capacity or about at least a portion of a periphery of the at least one region for management of thermal capacity as well as non-conductive regions and is solidified about at least a portion of a periphery of the at least one non-conductive region forming an integral structure.

19. The apparatus of claim 17 wherein at least one region for management of electrical power capacity or one region for management of thermal capacity is accessible at a portion of the substrate member for contact with an electric power source or heat source or a power- or heat-requiring member.
